(19) United States
(12) Patent Application Publication
(10) Pub. No.: US 2026/0227704 A1
(43) Pub. Date: Aug. 6, 2026

(54) FLUID HANDLING SYSTEM AND METHOD IN WHICH DEFECTS DUE TO LIQUID LEFT ON A SUBSTRATE CAN BE REDUCED AND LITHOGRAPHIC APPARATUS COMPRISING THE FLUID HANDLING SYSTEM

(71) Applicant: ASML NETHERLANDS B.V., Veldhoven (NL)

(72) Inventors: Yuk Man LAU, Eindhoven (NL); Ankur KISLAYA, Veldhoven (NL); Marlies Maria Egidius VAN OSCH, Breda (NL)

(73) Assignee: ASML NETHERLANDS B.V., Veldhoven (NL)

(21) Appl. No.: 19/155,459

(22) PCT Filed: Jan. 23, 2024
(86) PCT No.: PCT/EP2024/051505

§ 371 Date: Aug. 11, 2025

(30) Foreign Application Priority Data
Feb. 21, 2023 (EP) 23157818.8

(51) Int. Cl. G03F 7/00; G03F 7/20

(52) U.S. Cl. CPC G03F 7/70341; G03F 7/20

(57) ABSTRACT

A fluid handling structure for an immersion lithographic apparatus, the fluid handling structure configured to confine immersion liquid to a space between a bottom surface of the fluid handling structure and a surface of a substrate and/or a substrate support supporting the substrate, the structure having: a feature in the bottom surface having a substantially polygonal shape defined by a plurality of sides; an opening configured to supply immersion fluid to the space; an extractor configured to extract immersion fluid from the space; and an immersion fluid recovery arrangement outside the feature and proximate a side of the feature, wherein the immersion fluid recovery arrangement includes an immersion fluid manipulator configured to form an elongate wiper zone extending at an angle to the side of the feature and an immersion fluid recovery opening for extracting immersion fluid.

### CROSS-REFERENCE TO RELATED APPLICATIONS

This application claims priority of EP application 23157818.8 which was filed on 21 Feb. 2023 and which is incorporated herein in its entirety by reference.

### FIELD

The present invention relates to a fluid handling structure and a device manufacturing method. The present invention also relates to a lithographic apparatus comprising the fluid handling structure.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, use a projection system to project a pattern (also often referred to as “design layout” or “design”) of a patterning device (e.g., a mask) onto a layer of radiation-sensitive material (resist) provided on a substrate (e.g., a wafer). Known lithographic apparatus include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the substrate parallel or anti-parallel to this direction.

As semiconductor manufacturing processes continue to advance, the dimensions of circuit elements have continually been reduced while the amount of functional elements, such as transistors, per device has been steadily increasing over decades, following a trend commonly referred to as ‘Moore's law’. To keep up with Moore's law the semiconductor industry is chasing technologies that enable to create increasingly smaller features. To project a pattern on a substrate a lithographic apparatus may use electromagnetic radiation. The wavelength of this radiation determines the minimum size of features which are patterned on the substrate. Typical wavelengths currently in use are 365 nm (i-line), 248 nm, 193 nm and 13.5 nm.

Further improvements in the resolution of smaller features may be achieved by providing an immersion fluid having a relatively high refractive index, such as water, on the substrate during exposure. The effect of the immersion fluid is to enable imaging of smaller features since the exposure radiation will have a shorter wavelength in the fluid than in gas. The effect of the immersion fluid may also be regarded as increasing the effective numerical aperture (NA) of the system and also increasing the depth of focus.

The immersion fluid may be confined to a localized area between the projection system of the lithographic apparatus and the substrate by a fluid handling structure.

In a lithography apparatus using immersion liquid (often referred to as an immersion lithography apparatus) liquid droplets or films left on the substrate may lead to defects. For example, if the meniscus of the immersion liquid filling an immersion space between the projection lens and the substrate collides with a droplet left on the substrate, a bubble of gas (e.g. air) may get into the immersion liquid and enter the beam path. Bubbles in the beam path may distort the image projected onto the substrate and lead to defects. Also, liquid droplets or films may lead to drying marks on the resist (known as “watermarks”).

Existing arrangements have proven effective at controlling immersion liquid. However, it is desired to improve the throughput of lithography apparatus, which means in the case of immersion lithography apparatus, increasing the speed of relative motion between the substrate and the immersion liquid. Existing fluid handling structures may not be as effective at such higher speeds.

### SUMMARY

It is an object of the present invention to provide a fluid handling system and method in which defects due to liquid left on the substrate can be reduced, even at high speeds of relative motion of the substrate.

According to a first aspect of the invention, there is provided a fluid handling structure for an immersion lithographic apparatus, the fluid handling structure configured to confine immersion liquid to a space between a bottom surface of the fluid handling structure and a surface of a substrate and/or a substrate support supporting the substrate, the structure having: a feature in the bottom surface having a substantially polygonal shape defined by a plurality of sides; an opening configured to supply immersion fluid to the space; an extractor configured to extract immersion fluid from the space; and an immersion fluid recovery arrangement outside the feature and proximate a side of the feature, wherein the immersion fluid recovery arrangement comprises an immersion fluid manipulator configured to form an elongate wiper zone extending at an angle to the side of the feature and an immersion fluid recovery opening for extracting immersion fluid.

According to a second aspect of the invention, there is provided a lithographic apparatus having a substrate holder configured to hold a substrate, a projection system configured to project a radiation beam onto the substrate held by the substrate holder, and a fluid handling structure as described above.

According to a third aspect of the invention, there is provided a device manufacturing a device manufacturing method in a lithographic apparatus having a substrate holder configured to hold a substrate, a projection system configured to project a radiation beam onto the substrate held by the substrate holder, and a fluid handling structure according to any preceding claim, the method comprising using the fluid handling structure to confine immersion fluid to a space between at least a part of the fluid handling structure and the surface of the substrate; using the immersion fluid recovery arrangement to recover immersion fluid that has escaped confinement by the fluid handling structure.

Further embodiments, features and advantages of the present invention, as well as the structure and operation of the various embodiments, features and advantages of the present invention, are described in detail below with reference to the accompanying drawings.

### DESCRIPTION OF THE DRAWINGS

Embodiments of the invention will now be described, by way of example only, with reference to the accompanying schematic drawings, in which corresponding reference symbols indicate corresponding parts, and in which:

FIG. 1 depicts the schematic overview of the lithographic apparatus;

FIG. 2 is a schematic cross-section of a fluid handling structure;

FIG. 3 is a schematic cross-section of another fluid handling structure;

FIG. 4 is a schematic plan view of a fluid handling system;

FIGS. 5A to 5D depict immersion fluid recovery arrangements of embodiments of the invention;

FIG. 6 is a schematic plan view of a fluid handling system having immersion fluid recovery arrangements; and

FIG. 7 is a schematic plan view of another fluid handling system having immersion fluid recovery arrangements.

The features shown in the figures are not necessarily to scale, and the size and/or arrangement depicted is not limiting. It will be understood that the figures include optional features which may not be essential to the invention. Furthermore, not all of the features of the apparatus are depicted in each of the figures, and the figures may only show some of the components relevant for describing a particular feature.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

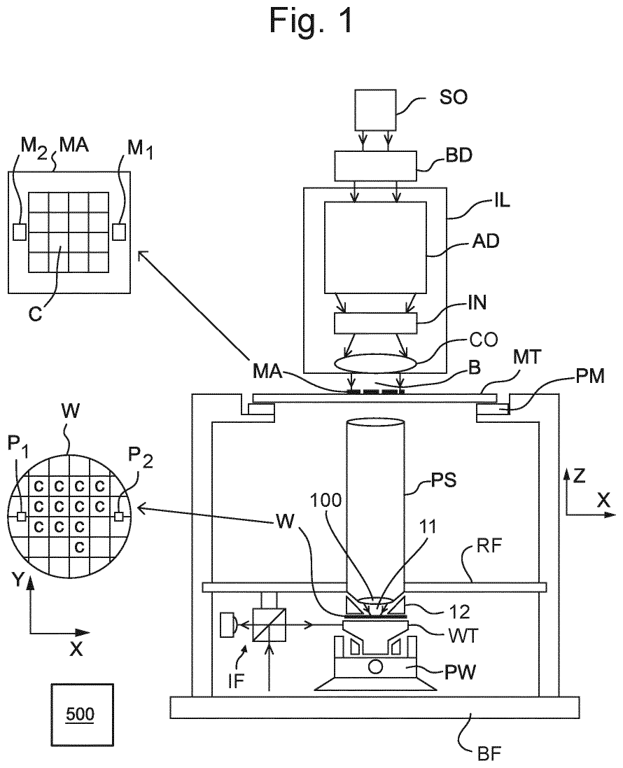

FIG. 1 schematically depicts a lithographic apparatus. The lithographic apparatus includes an illumination system (also referred to as illuminator) IL configured to condition a radiation beam B (e.g., UV radiation or DUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a substrate table) WT constructed to hold a substrate (e.g., a resist coated wafer) W and connected to a second positioner PW configured to accurately position the substrate support WT in accordance with certain parameters, and a projection system (e.g., a refractive projection lens system) PS configured to project a pattern imparted to the radiation beam B by patterning device MA onto a target portion C (e.g., comprising one or more dies) of the substrate W. A controller 500 controls the overall operation of the apparatus. Controller 500 may be a centralised control system or a system of multiple separate sub-controllers within various sub-systems of the lithographic apparatus.

In operation, the illumination system IL receives the radiation beam B from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus is of a type wherein at least a portion of the substrate W may be covered by an immersion liquid having a relatively high refractive index, e.g., water, so as to fill an immersion space 11 between the projection system PS and the substrate W-which is also referred to as immersion lithography. More information on immersion techniques is given in U.S. Pat. No. 6,952,253, which is incorporated herein by reference.

The lithographic apparatus may be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus may comprise a measurement stage (not depicted in figures). The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

To clarify the invention, a Cartesian coordinate system is used. The Cartesian coordinate system has three axis, i.e., an x-axis, a y-axis and a z-axis. Each of the three axis is orthogonal to the other two axis. A rotation around the x-axis is referred to as an Rx-rotation. A rotation around the y-axis is referred to as an Ry-rotation. A rotation around about the z-axis is referred to as an Rz-rotation. The x-axis and the y-axis define a horizontal plane, whereas the z-axis is in a vertical direction. The Cartesian coordinate system is not limiting the invention and is used for clarification only. Instead, another coordinate system, such as a cylindrical coordinate system, may be used to clarify the invention. The orientation of the Cartesian coordinate system may be different, for example, such that the z-axis has a component along the horizontal plane.

Immersion techniques have been introduced into lithographic systems to enable improved resolution of smaller features. In an immersion lithographic apparatus, a liquid layer of immersion liquid having a relatively high refractive index is interposed in the immersion space 11 between a projection system PS of the apparatus (through which the patterned beam is projected towards the substrate W) and the substrate W. The immersion liquid covers at least the part of the substrate W under a final element of the projection system PS. Thus, at least the portion of the substrate W undergoing exposure is immersed in the immersion liquid.

In commercial immersion lithography, the immersion liquid is water. Typically the water is distilled water of high purity, such as Ultra-Pure Water (UPW) which is commonly used in semiconductor fabrication plants. In an immersion system, the UPW is often purified and it may undergo additional treatment steps before supply to the immersion space 11 as immersion liquid.

Other liquids with a high refractive index can be used besides water as the immersion liquid, for example: a hydrocarbon, such as a fluorohydrocarbon; and/or an aqueous solution. Further, other fluids besides liquid have been envisaged for use in immersion lithography.

In this specification, reference will be made in the description to localized immersion in which the immersion liquid is confined, in use, to the immersion space 11 between the final element 100 and a surface facing the final element 100. The facing surface is a surface of substrate W or a surface of the supporting stage (or substrate support WT) that is co-planar with the surface of the substrate W. (Please note that reference in the following text to surface of the substrate W also refers in addition or in the alternative to the surface of the substrate support WT, unless expressly stated otherwise; and vice versa). A fluid handling structure 12 present between the projection system PS and the substrate support WT is used to confine the immersion liquid to the immersion space 11. The immersion space 11 filled by the immersion liquid is smaller in plan than the top surface of the substrate W and the immersion space 11 remains substantially stationary relative to the projection system PS while the substrate W and substrate support WT move underneath.

Other immersion systems have been envisaged such as an unconfined immersion system (a so-called ‘All Wet’ immersion system) and a bath immersion system. In an unconfined immersion system, the immersion liquid covers more than the surface under the final element 100. The liquid outside the immersion space 11 is present as a thin liquid film. The liquid may cover the whole surface of the substrate W or even the substrate W and the substrate support WT co-planar with the substrate W. In a bath type system, the substrate W is fully immersed in a bath of immersion liquid.

The fluid handling structure 12 is a structure which supplies the immersion liquid to the immersion space 11, removes the immersion liquid from the immersion space 11 and thereby confines the immersion liquid to the immersion space 11. It includes features which are a part of a fluid supply system. The arrangement disclosed in PCT patent application publication no. WO 99/49504 is an early fluid handling structure comprising pipes which either supply or recover the immersion liquid from the immersion space 11 and which operate depending on the relative motion of the stage beneath the projection system PS. In more recent designs, the fluid handling structure extends along at least a part of a boundary of the immersion space 11 between the final element 100 of the projection system PS and the substrate support WT or substrate W, so as to in part define the immersion space 11.

The fluid handing structure 12 may have a selection of different functions. Each function may be derived from a corresponding feature that enables the fluid handling structure 12 to achieve that function. The fluid handling structure 12 may be referred to by a number of different terms, each referring to a function, such as barrier member, seal member, fluid supply system, fluid removal system, liquid confinement structure, etc.

Immersion liquid can be used as the immersion fluid. In that case the fluid handling structure 12 may be a liquid handling system. In reference to the aforementioned description, reference in this paragraph to a feature defined with respect to fluid may be understood to include a feature defined with respect to liquid.

A lithographic apparatus has a projection system PS. During exposure of a substrate W, the projection system PS projects a beam of patterned radiation onto the substrate W. To reach the substrate W, the path of the radiation beam B passes from the projection system PS through the immersion liquid confined by the fluid handling structure 12 between the projection system PS and the substrate W. The projection system PS has a lens element, the last in the path of the beam, which is in contact with the immersion liquid. This lens element which is in contact with the immersion liquid may be referred to as ‘the last lens element’ or “the final element”. The final element 100 is at least partly surrounded by the fluid handling structure 12. The fluid handling structure 12 may confine the immersion liquid under the final element 100 and above the facing surface.

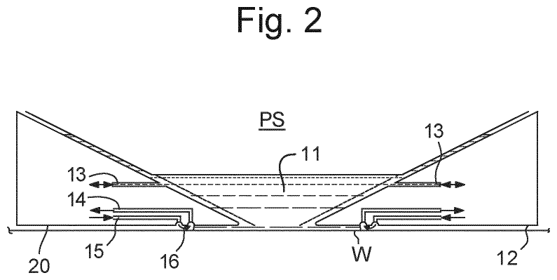

FIG. 2 schematically depicts a localized liquid supply system or fluid handling system. The liquid supply system is provided with a fluid handling structure 12 (or liquid confinement structure), which extends along at least a part of a boundary of the space 11 between the final element of the projection system PS and the support table WT or substrate W. The fluid handling structure 12 is substantially stationary relative to the projection system PS in the XY plane though there may be some relative movement in the Z direction (in the direction of the optical axis). In an example, a seal is formed between the fluid handling structure 12 and the surface of the substrate W and may be a contactless seal such as a gas seal (such a system with a gas seal is disclosed in EP1,420,298) or liquid seal.

The fluid handling structure 12 at least partly confines the immersion liquid in the space 11 between the final element of the projection system PS and the substrate W. The space 11 is at least partly formed by the fluid handling structure 12 positioned below and surrounding the final element 100 of the projection system PS. Immersion liquid is brought into the space 11 below the projection system PS and within the fluid handling structure 12 by one of liquid openings 13. The immersion liquid may be removed by another of liquid openings 13. The immersion liquid may be brought into the space 11 through at least two liquid openings 13. Which of liquid openings 13 is used to supply the immersion liquid and optionally which is used to remove the immersion liquid may depend on the direction of motion of the support table WT.

The immersion liquid may be confined in the space 11 by a contactless seal such as a gas seal 16 formed by a gas which, during use, is formed between the bottom of the fluid handling structure 12 and the surface of the substrate W. The gas in the gas seal 16 is provided under pressure via inlet 15 to the gap between the fluid handling structure 12 and substrate W. The gas is extracted via outlet 14. The overpressure on the gas inlet 15, vacuum level on the outlet 14 and geometry of the gap are arranged so that there is a high-velocity gas flow inwardly that confines the immersion liquid. Such a system is disclosed in US 2004/0207824, which is hereby incorporated by reference in its entirety. In an example, the fluid handling structure 12 does not have the gas seal 16.

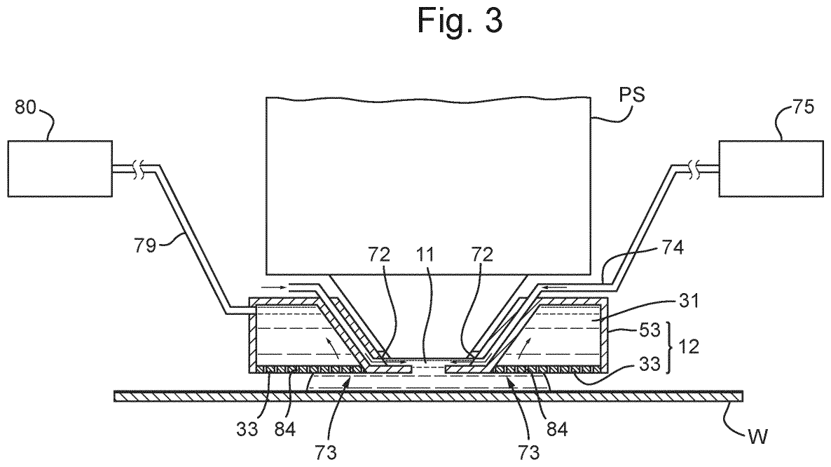

FIG. 3 is a side cross sectional view that depicts a further liquid supply system or fluid handling system according to an embodiment. The arrangement illustrated in FIG. 3 and described below may be applied to the lithographic apparatus described above and illustrated in FIG. 1. The liquid supply system is provided with a fluid handling structure 12 (or a liquid confinement structure), which extends along at least a part of a boundary of the space 11 between the final element of the projection system PS and the support table WT or substrate W.

The fluid handling structure 12 at least partly confines the immersion liquid in the space 11 between the final element of the projection system PS and the substrate W. The space 11 is at least partly formed by the fluid handling structure 12 positioned below and surrounding the final element of the projection system PS. In an example, the fluid handling structure 12 comprises a main body member 53 and a porous member 33. The porous member 33 is plate shaped and has a plurality of holes (i.e., openings or pores). In an example, the porous member 33 is a mesh plate wherein numerous small holes 84 are formed in a mesh. Such a system is disclosed in US 2010/0045949 A1, which is hereby incorporated by reference in its entirety.

The main body member 53 comprises supply ports 72, which are capable of supplying the immersion liquid to the space 11, and a recovery port 73, which is capable of recovering the immersion liquid from the space 11. The supply ports 72 are connected to a liquid supply apparatus 75 via passageways 74. The liquid supply apparatus 75 is capable of supplying the immersion liquid to the supply ports 72 through the corresponding passageway 74. The recovery port 73 is capable of recovering the immersion liquid from the space 11. The recovery port 73 is connected to a liquid recovery apparatus 80 via a passageway 79. The liquid recovery apparatus 80 recovers the immersion liquid recovered via the recovery port 73 through the passageway 79. The porous member 33 is disposed in the recovery port 73. Performing the liquid supply operation using the supply ports 72 and the liquid recovery operation using the porous member 33 forms the space 11 between the projection system PS and the fluid handling structure 12 on one side and the substrate W on the other side.

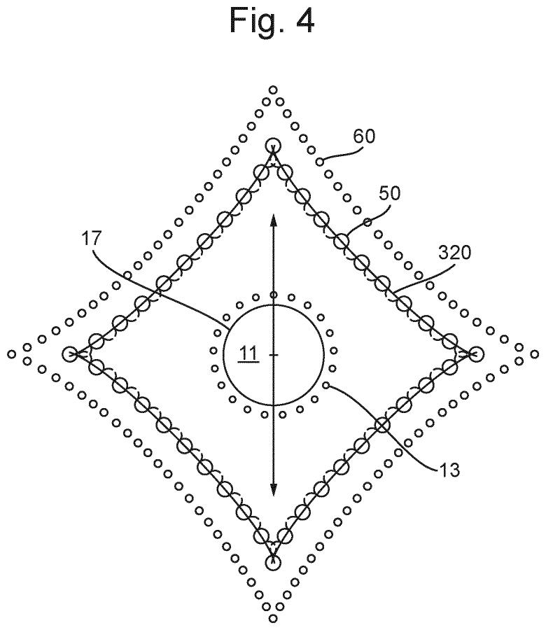

FIG. 4 illustrates schematically and in plan meniscus controlling features of an alternative fluid handling structure 12 provided to a surface 20 (indicated in FIG. 2) which may have outlets using the gas drag principle and to which an embodiment of the present invention may relate. The features of a meniscus controlling feature which are illustrated may, for example, replace the meniscus controlling features depicted in FIG. 2. The meniscus controlling feature of FIG. 4 is a form of extractor, for example a dual phase extractor. The meniscus controlling feature comprises a plurality of discrete openings 50 in the surface 20 of the fluid handling structure 12. Each discrete opening 50 is illustrated as being circular, though this is not necessarily the case.

Radially inwardly of the discrete openings 50 and also in the surface 20 of the fluid handling structure 12 are a plurality of outlet openings 13. Immersion liquid is provided through outlet openings 13 to the immersion space 11. Outlet openings 13 surround the space 11 which is bounded by the aperture 17 formed in the fluid handling structure 12. As with the corresponding openings in FIG. 2, openings 13 can also be used to extract immersion liquid depending on the direction of movement of the substrate. The meniscus 320 is pinned between the discrete openings 50 with drag forces induced by gas flow into the discrete openings 50.

Radially outward of the meniscus controlling features (discrete openings 50) are a plurality of gas knife openings 60. In use, gas knife openings 60 are provided with a flow of gas, e.g. humidified CO2, so as to form a region of high pressure on the surface of the substrate W that functions to push fluid that may be present on the surface of substrate W away from meniscus 320. In some embodiments, gas knife openings 60 may be omitted.

Various geometries of the bottom of the fluid handling structure are possible. For example, any of the structures disclosed in US 2004/0207824 or US 2010/0313974 could be used in an embodiment of the present invention. An embodiment of the invention may be applied to a fluid handling structure 12 which has any shape in plan, or has a feature such as the discrete openings 50 arranged in any shape, e.g., a circle, a square or a rhombus, etc .. Where a plurality of gas knife openings 60 is provided, the gas knife openings 60 may be arranged in a shape that it similar to the shape of the discrete openings 50.

In an immersion lithographic apparatus, immersion liquid is often left on the surface of the substrate W where the immersion fluid has passed. The immersion fluid left on the substrate W may form droplets and/or films. Immersion liquid left on the substrate W is known to cause at least two problems. First of all, when the immersion liquid dries it may leave a drying spot (also called a watermark) and/or affect the chemistry of the resist. Secondly, if a droplet collides with the meniscus 320 of the immersion liquid that is confined to the immersion space 11, the resulting disturbance of the meniscus 320 can result in bubbles of gas entering the immersion liquid. Bubbles that enter the immersion liquid may adhere to the surface of the substrate W or float freely within the immersion liquid. In either case, such bubbles can cause imaging defects that reduce yield. Bubble mitigation strategies are known, for example ensuring that the environment in the vicinity of the meniscus is mostly or entirely CO₂, which dissolves more quickly in water than N₂ or O₂ so that the likelihood of a CO₂ bubble dissolving before it reaches the projection beam is higher than the likelihood of an air bubble dissolving before it reaches the projection beam.

However, in order to provide lithographic apparatus having a higher throughput, it is desirable to increase the speed of relative movement of the substrate W and immersion liquid. With higher speeds, the probability of immersion liquid being left on the substrate W and the probability of generation of a bubble in the event of a collision between a liquid droplet on the surface of the substrate W and the meniscus 320 are increased. Therefore, there is a risk that in simply increasing the speed of movement of the substrate W, any gain in throughput would be lost by a reduction in yield. Therefore, the present invention proposes arrangements to prevent any liquid that has been left on the substrate W causing generation of bubbles in the immersion liquid and/or watermarks on the photo-resist.

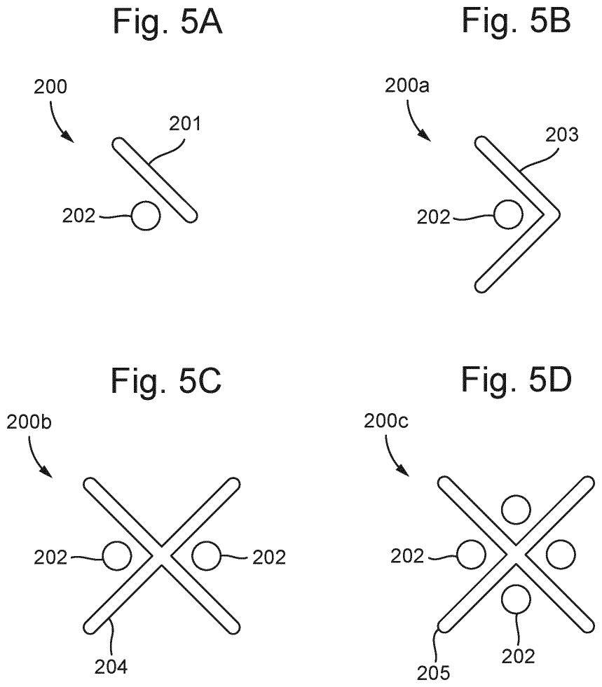

Accordingly, the present invention proposes one or more immersion fluid recovery arrangements provided in the fluid handling structure 12 outside any features of the fluid handling structure 12 that confine the immersion fluid. The immersion fluid recovery arrangements are configured to remove immersion liquid from the surface of the substrate W, specifically immersion liquid that has escaped from confinement to the immersion space 11 and has been left on the surface of the substrate W. Various examples of immersion fluid recovery arrangements are illustrated in FIGS. 5A to 5D.

FIG. 5A illustrates a simple example of an immersion fluid recovery arrangement 200 which comprises an immersion fluid manipulator 201 and an immersion fluid recovery opening 202 through which immersion fluid can be extracted. Immersion fluid manipulator 201 comprises an elongate opening connected to a high-pressure gas supply and facing the upper surface of the substrate W. Gas exiting the immersion fluid manipulator opening 201 forms a high-pressure region on the surface of the substrate W acting as a “wiper zone” to manipulate droplets or films of immersion liquid that may be on the surface of the substrate W. Immersion fluid manipulator opening 201 may be configured to form a gas knife on the substrate surface. Immersion fluid recovery opening 202 is connected to a low pressure so as to extract immersion liquid, e.g. as a two-phase flow. Immersion fluid recovery opening 202 may be connected to the same extraction channel as discrete openings 50 or outlet 14 or recovery port 73. Immersion fluid recovery opening 202 may be connected to a dedicated extraction channel.

When the substrate W moves under the immersion fluid manipulator opening 201, immersion liquid on the surface of the substrate W may be pushed across the surface of the substrate W in a desired direction. In particular, the immersion fluid manipulator opening 201 may be oriented at an angle to the direction of motion of the substrate W. This means that immersion liquid droplets on the surface of the substrate W are moved in a direction having a component perpendicular to the direction of motion of the substrate W. The immersion liquid on the surface of the substrate W can therefore be pushed towards immersion fluid recovery opening 202.

It will be appreciated that whilst immersion fluid manipulator opening 201 is illustrated in FIG. 5A as an elongate slit, it may be made up of a series of discrete openings arranged in a line. The discrete openings may themselves be slit-like, square, circular or other convenient shape. Circular openings may in some cases be more convenient to manufacture. Gas supplied to the immersion fluid manipulator opening 201 may be, for example, CO₂. Gas supplied to immersion fluid manipulator opening 201 may be humidified in order to reduce a thermal load that would be caused by evaporation of the immersion liquid in an extraction channel. Especially if the immersion fluid manipulator opening 201 is further away from the meniscus 320, the gas supplied to it may be air or artificial air (e.g. CDA or XCDA).

Immersion fluid recovery opening 202 is located close to an end of immersion fluid manipulator opening 201 such that, in use, there is a sufficient flow of gas from immersion fluid manipulator opening 201 to immersion fluid recovery opening 202 to cause immersion fluid left on the substrate W to be drawn into immersion fluid recovery opening 202. Immersion fluid recovery opening 202 is shown as being circular in plan, which may be convenient to manufacture, but other shapes are possible. For example, an elongate slit may be advantageous in some cases. Immersion fluid recovery opening 202 may also be formed as a cluster of discrete openings of any convenient shape in any convenient arrangement.

FIG. 5B depicts a further immersion fluid recovery arrangement 200a. Immersion fluid recovery arrangement 200a differs from immersion fluid recovery arrangement 200 in that it comprises an immersion fluid manipulator opening 203 that is V-shaped. Immersion fluid recovery opening 202 is located within the V-shape of immersion fluid manipulator opening 203 close to the apex thereof. Immersion fluid recovery arrangement 200a can recover immersion fluid from a wider strip of the substrate W than immersion fluid recovery arrangement 200. The V-shaped arrangement of immersion fluid manipulator opening 203, and the wiper zone created thereby, can reliably direct immersion fluid to a location where it can be extracted through immersion fluid recovery opening 202 and not just be pushed around on the surface of the substrate W. Other than the shape of immersion fluid manipulator opening 203, immersion fluid recovery arrangement 200a may be the same as immersion fluid recovery arrangement 200.

FIG. 5C depicts a further immersion fluid recovery arrangement 200b. Immersion fluid recovery arrangement 200b comprises an X-shaped immersion fluid manipulator opening 204 and a pair of immersion fluid recovery openings 202 located within opposite quadrants defined by immersion fluid manipulator opening 204. Immersion fluid recovery arrangement 200b is effective to recover immersion fluid from the surface of the substrate W when the substrate W is moving either forward or backward along a line between the two immersion fluid recovery openings 202 (horizontally in the figure). Other than in the shape of the immersion fluid manipulator opening 204, immersion fluid recovery arrangement 200b may be the same as immersion fluid recovery agent 200.

FIG. 5D depicts a further immersion fluid recovery arrangement 200c. Immersion fluid recovery arrangement 200c comprises an X-shaped immersion fluid manipulator opening 205 and four immersion fluid recovery openings 202. One of the four immersion fluid recovery openings 202 is located in each quadrant defined by X-shaped immersion fluid manipulator opening 205. It will be appreciated that immersion fluid recovery arrangement 200c is effective to recover immersion liquid left on the surface of the substrate W when the substrate is moving in any direction. Other than in the number of immersion fluid recovery openings 202 and the shape of immersion fluid manipulator opening 205, immersion fluid recovery arrangement 200c may be the same as immersion fluid recovery arrangement 200.

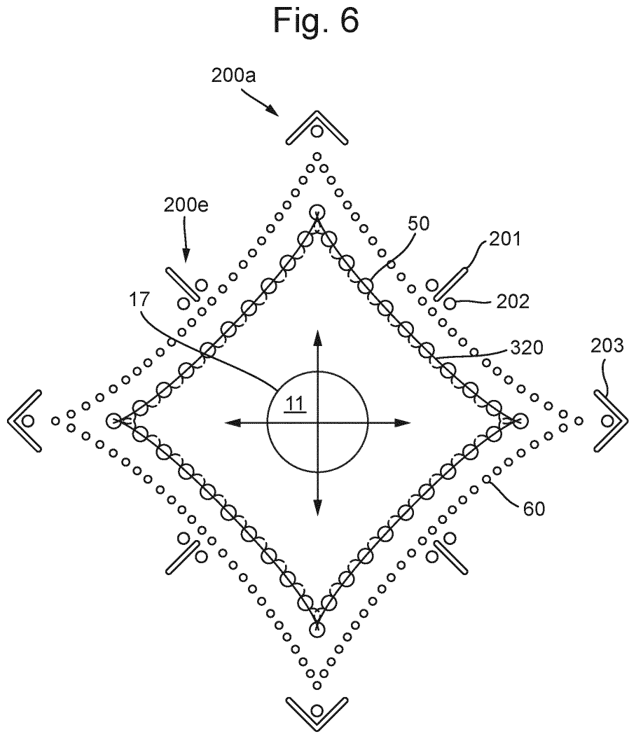

It will be appreciated that immersion fluid recovery arrangements 200, 200a, 200b, 200c may be located anywhere convenient on the surface 20 of fluid handling structure 12 facing the substrate W. Some possible locations are illustrated in FIG. 6. The fluid handling structure depicted in FIG. 6 has fluid handling features, specifically gas knife openings 60 and meniscus controlling features (discrete openings 50) that are arranged in a four-sided shape. The four-sided shape resembles a rhombus or diamond (i.e. a square with diagonals parallel to the x and y-axis) which has been found to be an effective shape for movements of the substrate W relative to the fluid handling structure 12 in the x and y directions. It is to be noted that the sides of the four-sided shape are not straight but slightly curved (concave) so that the corners of the four-sided shape are more pointy.

As depicted in FIG. 6, an immersion fluid recovery arrangement 200a with a V-shaped immersion fluid manipulator opening 201 is arranged adjacent each corner of the four-sided shape, orientated such that the point of the V-shape of immersion fluid manipulator 203 points in the same direction of the corner of the four-sided shape. A further immersion fluid recovery arrangement 200e is located near a central region of each side of the four-sided shape, e.g. close to the midpoint of each side. There can be more than one immersion fluid recovery arrangement 200e adjacent each side of the four-sided shape. Immersion liquid recovery arrangement 200e comprises a straight elongate immersion fluid manipulator opening 201 and two immersion fluid recovery openings 202 adjacent the end of immersion fluid manipulator opening 201 that is closest to the side of the four-sided shape.

Immersion fluid manipulator opening 201 of immersion fluid recovery arrangement 200e extends at an angle to the side of the four-sided shape to which it is adjacent. Immersion fluid manipulator opening 201 may extend perpendicularly to the side of the four-sided shape, i.e. at right angles to a tangent to the side at the closest point. More generally, the acute angle between the immersion fluid manipulator opening 201 and the side of the four-sided shape may be greater than 45°, greater than 60°, desirably greater than 70°, more desirably greater than 80°. Immersion fluid manipulator opening 201 may be slightly curved similarly to the four-sided shape.

The immersion fluid recovery arrangements 200e that are provided adjacent the midpoints of the sides of the four-sided shape have been determined by the inventors to be effective, especially operating in combination with gas knife openings 60, at sweeping up any immersion liquid that has been left on the edge of the substrate W. This positioning is also effective at protecting parts of the meniscus 320 that may be vulnerable to inclusion of gas bubbles. Immersion fluid recovery arrangements 200a that are provided adjacent the corners of the four-sided shape, are effective at collecting immersion liquid that escapes from the immersion space 11 through film pulling. It will therefore be appreciated that locations for immersion liquid recovery arrangements 200, 200a, 200b, 200c may be chosen on the basis of either quickly recovering any escaped immersion liquid or protecting locations where collisions with droplets are most likely to give rise to creation of bubbles in the immersion space 11.

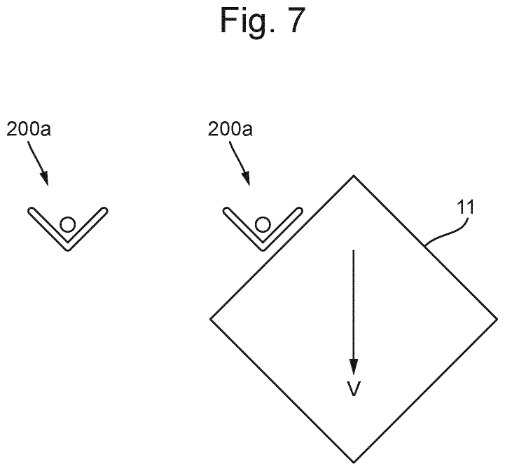

FIG. 7 depicts an embodiment in which two immersion fluid recovery arrangements 200a are provided on one side of an immersion space 11. In this embodiment, the substrate W moves in the direction indicated by arrow V during exposures. The immersion fluid recovery arrangements 200a are positioned to the side where previous exposures were carried out in order to recover immersion fluid left behind during prior exposures. One immersion fluid recovery arrangement 200a is positioned close to immersion space 11 to protect the meniscus 320 of the immersion liquid and prevent creation of bubbles. Another immersion fluid recovery arrangement 200a is spaced away from the immersion space 11 and functions to recover immersion fluid from previous passes to prevent the creation of drying spots.

The immersion fluid recovery arrangements 200, 200a, 200b, 200c described above, can be operated continuously whilst scanning of substrates W is being performed or selectively during times or at locations when immersion liquid is most likely to be present or the meniscus is more vulnerable to generation of bubbles and/or watermarks. The immersion fluid manipulators 201, 203, 204, 205 and immersion fluid recovery openings 202 may be operated together or separately as required. For example, it may be desirable to operate the immersion fluid manipulators 201, 203, 204, 205 only at certain times in an exposure sequence in order to push residual immersion fluid to a gap at the edge of the substrate W where it can be recovered, rather than to the separate immersion fluid recovery openings 202.

The present invention may provide a lithographic apparatus. The lithographic apparatus may have any/all of the other features or components of the lithographic apparatus as described above. For example, the lithographic apparatus may optionally comprise at least one or more of a source SO, an illumination system IL, a projection system PS, a substrate support WT, etc ..

Specifically, the lithographic apparatus may comprise the projection system PS configured to project the radiation beam B towards the region of the surface of a substrate W. The lithographic apparatus may further comprise the fluid handling system as described in any of the above embodiments in FIGS. 2-4 and variations.

The lithographic apparatus may comprise an actuator (not shown) configured to move the substrate W relative to the fluid handling system. Thus, the actuator may be used to control the position of the substrate W (or alternatively, the position of the fluid handling system). The actuator could be, or could comprise, the substrate support (e.g., a substrate table) WT and/or a substrate holder constructed to hold the substrate W and/or the second positioner PW configured to accurately position the substrate support WT.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Where the context allows, embodiments of the invention may be implemented in hardware, firmware, software, or any combination thereof. Embodiments of the invention may also be implemented by instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

Although specific reference may be made in this text to embodiments of the invention in the context of a lithographic apparatus, embodiments of the invention may be used in other apparatus.

Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools. Such a lithographic tool may use ambient (non-vacuum) conditions.

Although specific reference may have been made above to the use of embodiments of the invention in the context of optical lithography, it will be appreciated that the invention, where the context allows, is not limited to optical lithography.

Embodiments include the following numbered clauses:

1. A fluid handling structure for an immersion lithographic apparatus, the fluid handling structure configured to confine immersion liquid to a space between a bottom surface of the fluid handling structure and a surface of a substrate and/or a substrate support supporting the substrate, the structure having: a feature in the bottom surface having a substantially polygonal shape defined by a plurality of sides; an opening configured to supply immersion fluid to the space; an extractor configured to extract immersion fluid from the space; and an immersion fluid recovery arrangement outside the feature and proximate a side of the feature, wherein the immersion fluid recovery arrangement comprises an immersion fluid manipulator configured to form an elongate wiper zone extending at an angle to the side of the feature and an immersion fluid recovery opening for extracting immersion fluid.

2. A fluid handling system according to clause 1 wherein the immersion fluid manipulator comprises a gas knife.

3. A fluid handling structure according to clause 2 wherein gas knife forms a high pressure region on the surface of the substrate and/or the substrate support as the elongate wiper zone.

4. A fluid handling structure according to clauses 1, 2 or 3 wherein acute angle between the elongate wiper zone and the side of the feature is greater than 45°, greater than 60°, desirably greater than 75°, more desirably greater than 85°.

5. A fluid handling structure according to any preceding clause wherein the immersion fluid manipulator is configured to form a further elongate wiper zone extending at an angle to the elongate wiper zone.

6. A fluid handling structure according to clause 5 wherein the further elongate wiper zone extends at an angle to the elongate wiper in the range of from 60° to 90°, desirably from 75° to 90°, more desirably from 85° to 90°.

7. A fluid handling structure according to any preceding clause wherein the immersion fluid manipulator is proximate a central region of the side, desirably the central region comprising a middle third of the side.

8. A fluid handling structure according to any preceding clause wherein the immersion fluid recovery arrangement comprises a plurality of immersion fluid recovery openings.

9. A fluid handling structure according to clause 8 wherein the immersion fluid recovery arrangement comprises an immersion fluid recovery opening on each side of the immersion fluid manipulator.

10. A fluid handling structure according to any preceding clause having a plurality of immersion fluid recovery arrangements.

11. A fluid handling structure according to clause 10 wherein the number of immersion fluid recovery arrangements is equal to or greater than the number of sides of the feature.

12. A fluid handling structure according to any preceding clause wherein the feature comprises a gas knife and/or the extractor.

13. A lithographic apparatus having a substrate holder configured to hold a substrate, a projection system configured to project a radiation beam onto the substrate held by the substrate holder, and a fluid handling structure according to any preceding clause.

14. A device manufacturing method in a lithographic apparatus having a substrate holder configured to hold a substrate, a projection system configured to project a radiation beam onto the substrate held by the substrate holder, and a fluid handling structure according to any preceding clause, the method comprising: using the fluid handling structure to confine immersion fluid to a space between at least a part of the fluid handling structure and the surface of the substrate; using the immersion fluid recovery arrangement to recover immersion fluid that has escaped confinement by the fluid handling structure.

15. A method according to clause 14 wherein the immersion fluid recovery arrangement is activated when a relative speed between the fluid handling structure and the substrate is greater than a predetermined threshold speed.

16. A method according to clause 14 wherein the fluid handling structure has a plurality of immersion fluid recovery arrangements and the immersion fluid recovery arrangements are selectively actuated depending on the direction of relative movement of the fluid handling structure and the substrate.

While specific embodiments of the invention have been described above, it will be appreciated that the invention may be practiced otherwise than as described. The descriptions above are intended to be illustrative, not limiting. Thus it will be apparent to one skilled in the art that modifications may be made to the invention as described without departing from the scope of the claims set out below.

1. A fluid handling structure for an immersion lithographic apparatus, the fluid handling structure configured to confine immersion liquid to a space between a bottom surface of the fluid handling structure and a surface of a substrate and/or a substrate support supporting the substrate, the fluid handling structure having:
a feature in the bottom surface having a substantially polygonal shape defined by a plurality of sides;
an opening configured to supply immersion fluid to the space;
an extractor configured to extract immersion fluid from the space; and
an immersion fluid recovery arrangement outside the feature and proximate a side of the feature, wherein the immersion fluid recovery arrangement comprises:
an immersion fluid manipulator comprising one or more fluid supply openings configured to form an elongate wiper zone extending at an angle to the side of the feature, wherein the angle is in the range of from about 60° to 90°, and
an immersion fluid recovery opening configured to extract immersion fluid.

2. The fluid handling structure system according to claim 1, wherein the one or more fluid supply openings form a gas knife.

3. The fluid handling structure according to claim 2, wherein gas knife forms a high pressure region on the surface of the substrate and/or the substrate support as the elongate wiper zone.

4. The fluid handling structure according to claim 1, wherein the acute angle between the elongate wiper zone and the side of the feature is greater than 75°.

5. The fluid handling structure according to claim 1, wherein the immersion fluid manipulator is configured to form a further elongate wiper zone extending at an angle to the elongate wiper zone.

6. The fluid handling structure according to claim 5, wherein the further elongate wiper zone extends at an angle to the elongate wiper in the range of from 60° to 90°.

7. The fluid handling structure according to claim 1, wherein the immersion fluid manipulator is proximate a central region of the side.

8. The fluid handling structure according to claim 1, wherein the immersion fluid recovery arrangement comprises a plurality of immersion fluid recovery openings.

9. The fluid handling structure according to claim 8, wherein the immersion fluid recovery arrangement comprises an immersion fluid recovery opening on each side of the immersion fluid manipulator.

10. The fluid handling structure according to claim 1, comprising a plurality of immersion fluid recovery arrangements.

11. The fluid handling structure according to claim 10, wherein the number of immersion fluid recovery arrangements is equal to or greater than the number of sides of the feature.

12. The fluid handling structure according to claim 1, wherein the feature comprises a gas knife and/or the extractor.

13. A lithographic apparatus comprising a substrate holder configured to hold a substrate, a projection system configured to project a radiation beam onto the substrate held by the substrate holder, and the fluid handling structure according to claim 1.

14. A device manufacturing method in a lithographic apparatus having a substrate holder configured to hold a substrate, a projection system configured to project a radiation beam onto the substrate held by the substrate holder, and the fluid handling structure according to claim 1, the method comprising:
using the fluid handling structure to confine immersion fluid to a space between at least a part of the fluid handling structure and the surface of the substrate; and
using the immersion fluid recovery arrangement to recover immersion fluid that has escaped confinement by the fluid handling structure.

15. The device manufacturing method according to claim 14, wherein the immersion fluid recovery arrangement is activated when a relative speed between the fluid handling structure and the substrate is greater than a predetermined threshold speed.

16. The device manufacturing method according to claim 14, wherein the fluid handling structure has a plurality of immersion fluid recovery arrangements and the immersion fluid recovery arrangements are selectively actuated depending on direction of relative movement between the fluid handling structure and the substrate.

17. The device manufacturing method according to claim 14, wherein the angle between the elongate wiper zone and the side of the feature is greater than 75°.

18. The device manufacturing method according to claim 14, wherein the immersion fluid manipulator is configured to form a further elongate wiper zone extending at an angle to the elongate wiper zone.

19. The device manufacturing method according to claim 18, wherein the further elongate wiper zone extends at an angle to the elongate wiper in the range of from 60° to 90°.

20. The device manufacturing method according to claim 14, wherein the immersion fluid manipulator is proximate a central region of the side.
